(19) United States
(12) Patent Application Publication
(10) Pub. No.: US 2008/0290481 A1
(43) Pub. Date: Nov. 27, 2008

(54) Semiconductor Device Package Leadframe

(76) Inventors: Takahiko Kudoh, Oita (JP); Lance Cole Wright, Allen, TX (US)

Correspondence Address: TEXAS INSTRUMENTS INCORPORATED, P O BOX 655474, M/S 3999, DALLAS, TX, 75265, US

(21) Appl. No.: 11/754,108

(22) Filed: May 25, 2007

(51) Int. Cl. H01L 23/495; H01R 43/00

(52) U.S. Cl. 257/670; 29/874; 257/E23.031

(57) ABSTRACT

The invention provides semiconductor device packages, leadframes, and methods for their manufacture, with improved characteristics for the formation of metallurgical joints. In a disclosed preferred embodiment of a semiconductor device leadframe according to the invention, a generally rectangular sheet metal body has a semiconductor device mounting site for receiving a semiconductor device. Leadfingers extend from the proximity of the device mounting site the outer edges of the leadframe. An anchor pad is included at each corner of the leadframe body, each anchor pad having a patterned surface. According disclosed aspects of the invention, the patterned surfaces of the anchor pads may include indented, embossed, or cut-out portions. According to other aspects of the invention, patterned anchor pad surfaces are plated with a low-melting point alloy and remain exposed at the corners of an encapsulated package.

### TECHNICAL FIELD

The invention relates to electronic semiconductor devices and manufacturing. More particularly, the invention relates to microelectronic semiconductor device package leadframes and to methods related to their manufacture.

### BACKGROUND OF THE INVENTION

It is conventional to incorporate one or more semiconductor devices mounted on a leadframe into a plastic semiconductor device package. These plastic packages are configured to protect the device(s) from the external environment, and provide an interface for electrically and mechanically incorporating the device into an apparatus or system. A metallic leadframe is typically the foundation of the semiconductor package, providing mechanical support to the or device during its assembly, and providing electrical contacts to the finished package. Generally, a leadframe includes a device paddle, to which the device is attached. The paddle is typically supported by tie bars connecting the corners of the paddle to the corners of the leadframe. Leadfingers, or ‘leads’, typically emanate from the paddle outward to the edges of the package. The device is ordinarily connected to the leads by wires through wirebonding or by tape automated bonding. After the paddle-mounted device is encapsulated in plastic mold compound, the leads provide external electrical connections between the terminals of the device and the outside world.

Leadframes are generally made from flat sheet metal, either by stamping or etching processes, or a combination thereof. Leadframe stamping is a mechanical process that employs die and punch sets to progressively shape the sheet metal into the intended leadframe configuration through a series of stamping and punching steps. Etching is a chemical process of selectively masking and etching portions of the sheet metal in accordance with the desired configuration of the leadframe. Following formation by stamping or etching, the leadframe is then finished by cleaning, plating, usually with highly conductive alloys, taping, and downsetting steps. Plating is applied to the leadfingers and device paddle in an effort to improve the adhesion of solder and die attach adhesive to the surfaces. Taping consists of putting a lead lock tape over the leads to prevent lead deformation during handling, while downsetting consists of pushing the paddle downward relative to the leadfingers and tie bars. Efforts are made to make leadframes from alloys that provide good adhesion to the mold compound, a coefficient of thermal expansion as close as possible to those of the attached device and the encapsulating mold compound, high strength, good formability, and high electrical and thermal conductivity.

Particularly with fine scale devices, the electrical connections alone, for example, solder ball connections to electrical contacts on the surface of a BGA (ball grid array), may provide insufficient mechanical strength and long-term durability for permanently affixing a package to a circuit board or other substrate. In an effort to overcome this problem, ‘anchor pads’ are sometimes incorporated into the leadframe corners. The anchor pads are generally used for completing mechanical, and not electrical, connections. The anchor pads known in the art are relatively large planar areas at the corners of a metallic leadframe. Their relatively large surface area offers additional soldering surface for the formation of solder joints between the leadframe and the mounting surface, such as a PCB (printed circuit board). Due to the inherent limitations in available area, increasing the strength and reliability of anchor pad solder joints remains a challenge to practitioners in the art.

Due to these and other technical challenges, improved semiconductor device leadframes with enhanced anchor pads, and related methods for their manufacture, would be useful and advantageous in the arts. The present invention is directed to overcoming, or at least reducing the effects of one or more of the problems noted herein.

### SUMMARY OF THE INVENTION

In carrying out the principles of the present invention, in accordance with preferred embodiments thereof, the invention provides leadframes, and methods for their manufacture, with improved characteristics for forming secure metallurgical joints.

According to one aspect of the invention, a preferred embodiment of a semiconductor device leadframe includes a generally rectangular sheet metal body. The leadframe has a semiconductor device mounting site for receiving a semiconductor device. Leadfingers extend from the proximity of the device mounting site the outer edges of the leadframe. An anchor pad is included at each corner of the leadframe body, each anchor pad having a patterned surface.

According to another aspect of the invention, in a preferred embodiment, a semiconductor device leadframe includes anchor pads having metallic surfaces punctuated by a plurality of indentations.

According to another aspect of the invention, in a semiconductor device leadframe exemplifying a preferred embodiment, each anchor pad includes a metallic surface punctuated by embossed portions.

According to another aspect of the invention, in a preferred embodiment, a semiconductor device leadframe includes anchor pads having a metallic surface punctuated by cut-outs.

According to yet another aspect of the invention, examples of preferred embodiments include semiconductor device leadframes with anchor pads bearing substantially grid-like patterns on their metallic surfaces.

According to another aspect of the invention, examples of preferred embodiments include semiconductor device leadframes with anchor pads bearing substantially circular patterns on their metallic surfaces.

According to still another aspect of the invention, semiconductor device leadframes within the scope of the invention include embodiments having anchor pads plated with a low-melting point alloy consisting of combinations which may include nickel, palladium, gold, silver, copper, tin.

The invention has advantages including but not limited to improving semiconductor device package strength and reliability, and improving mechanical connections at leadframe anchor pads. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a bottom view of an example of a preferred embodiment of a leadframe in a semiconductor device package according to the invention;

FIG. 2 is a macro bottom perspective view of a portion of the preferred embodiment of a leadframe according to the invention shown in FIG. 1;

FIG. 3 is a macro view of a portion of a preferred embodiment of a leadframe according to the invention;

FIG. 4 is a macro view of a portion of a preferred embodiment of a leadframe according to the invention;

FIG. 5 is a macro view of a portion of a preferred embodiment of a leadframe according to the invention; and

FIG. 6 is a macro view of a portion of a preferred embodiment of a leadframe according to the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### DESCRIPTION OF PREFERRED EMBODIMENTS

The invention provides semiconductor device package leadframes, and methods related to their manufacture, with improved metallurgical bonding characteristics and anchor pads configured for favorable bond formation, strength, and durability.

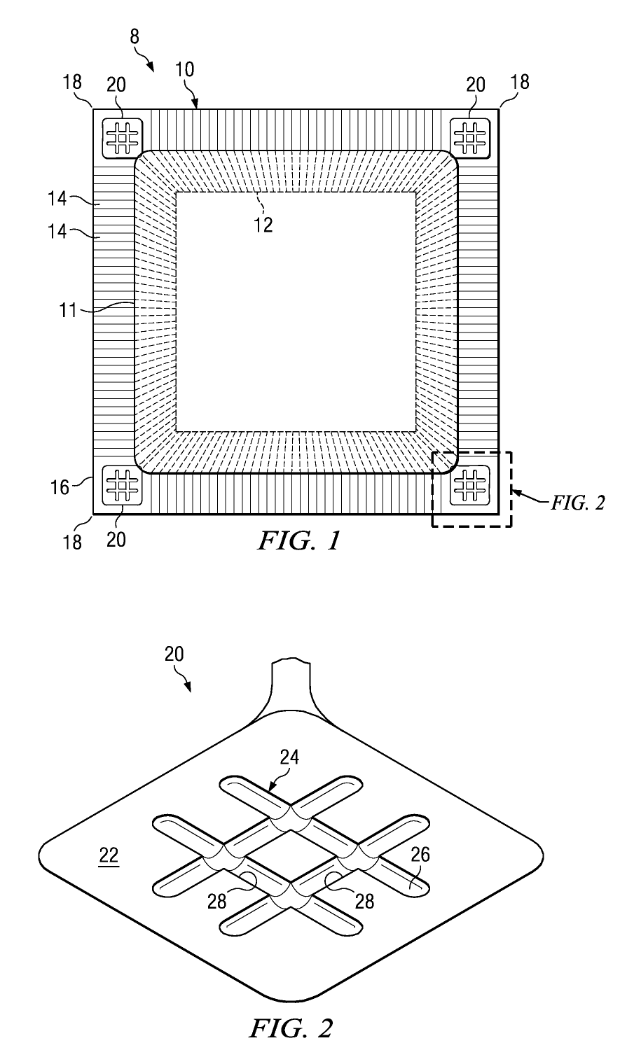

Referring initially to FIG. 1, a bottom view of an example of a preferred embodiment of a semiconductor device package 8 incorporating an improved leadframe 10 according to the invention is shown encapsulated in mold compound 11. The leadframe 10 is preferably formed from a more-or-less rectangular, or square, piece of sheet metal, generally made primarily of copper. A semiconductor device mounting site 12, sometimes called a device paddle, is provided as is familiar in the arts. Leadfingers 14 extend from the proximity of the device mounting site 12 to the leadframe edges 16. At or near the corners 18 of the leadframe 10, anchor pads 20 are provided. The anchor pads 20, also depicted in the more detailed macro perspective view of FIG. 2, are preferably more-or-less rectangular surfaces, in this case, approximately square, although other shapes may also be used, such as circular, hexagonal, etc. Preferably, the anchor pads 20 occupy the maximum area available, consistent with the limitations imposed by the geometry of the arrangement of leadfingers 14 and device mounting site 12, although other shapes and sizes may also be used within the scope of the invention. As illustrated in FIG. 2, the surface 22 of the anchor pads 20 deviates from smooth planarity by the incorporation of a textured pattern 24. In this particular example of a preferred embodiment, the pattern 24 is implemented in the form of indentations 26 stamped into the anchor pad 20 surface 22 in a more-or-less grid-like cross-hatching. The pattern 24, as shown, provides numerous edges 28 advantageous for the subsequent formation of metallurgical bonds in contact with the anchor pad 20. The pattern 24 of the anchor pads 20 may also be implemented using embossed portions, essentially the inverse of the indentations 26 of FIG. 2. Cut-out patterns may also be used within the scope of the invention as further described herein. Also, in alternatives to the substantially grid-like pattern 24 shown thus far, other patterns, such as substantially circular patterns, for example, may also be used without departure from the principals of the invention. It can be seen from FIG. 2 that the use of indented 26 patterns 24 may also increase the surface area available for metallurgical bond formation as well. It should be understood that the edges 28, as well as the increased surface area in embodiments so endowed, are advantageous for the formation of metallurgical bonds.

Preferably, the surfaces 22 of the anchor pads 20 are plated with one or more relatively low melting-point alloys in order to enhance the formation of strong and durable metallurgical bonds when the invention is used. Although other materials and various alloys may be used, in presently preferred embodiments of the invention, alloys made using combinations of two or more of the following metals are preferred: copper, nickel, tin, silver, gold, palladium. For example, in preferred embodiments, alloys made from combinations containing nickel, palladium, and gold, and alloys made from tin, silver, and copper, have been found suitable.

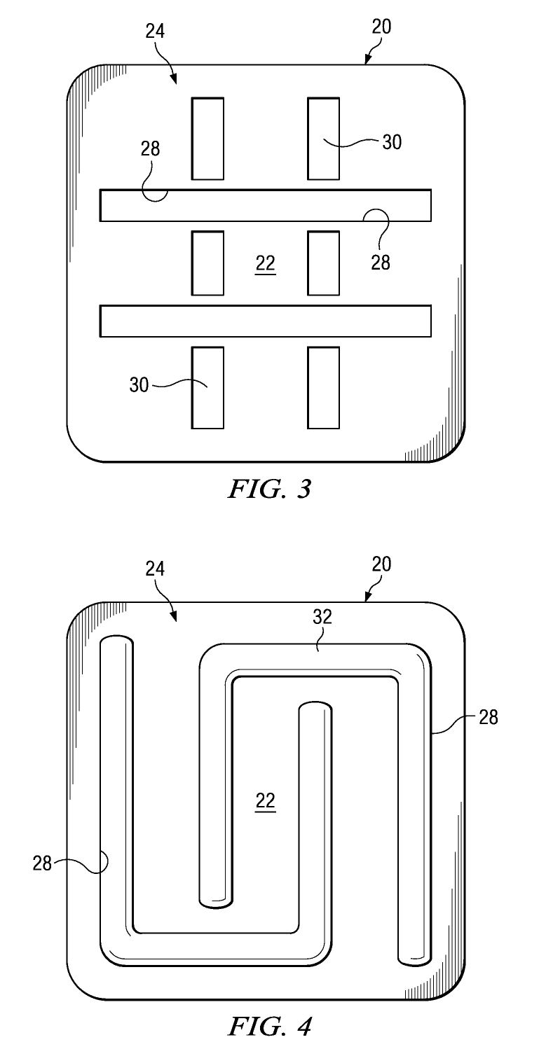

FIG. 3 is a macro view of a portion of another example of a preferred embodiment of a leadframe 10 according to the invention. In this example, the anchor pad 20 is a substantially rectangular area with a metallic surface 20 punctuated by a plurality of cut-outs 30 arranged in a substantially grid-like pattern 24. The cut-outs 30 may be cut, etched, punched, or drilled into the anchor pad 20. As can be seen in FIG. 3, edges 28 in the patterned 24 surface 22 are available for plating and metallic bond formation as described herein. Thus, although the surface area of the anchor pad 20 may be decreased be the cut-outs 30 in this particular embodiment, the edges 28 are nevertheless useful for the enhanced formation of metallurgical bonds.

An alternative preferred embodiment of the invention is illustrated in FIG. 4 in a macro view of a portion a leadframe 10. As shown in this example, the pattern 24 need not necessarily be laid out in a grid. The pattern 24 in this exemplary embodiment is implemented using a series of embossed portions 32 incorporated into the surface 22 of the anchor pad 20, showing another potential variation within the scope of the invention. Low melting-point alloy plating is preferably used as with other preferred embodiments of the invention. It can be seen from FIG. 4 that the use of an embossed 32 pattern 24 may also increase the surface area available for metallurgical bond formation as well as providing edges 28 to promote bonding.

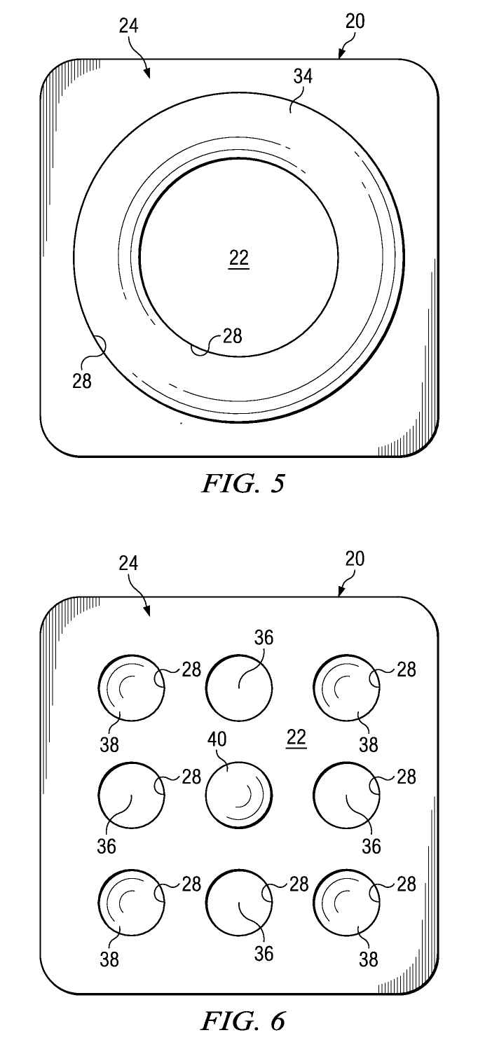

The possible alternative embodiments of the invention are numerous and cannot all be shown. An additional example appears in the FIG. 5 macro view of a portion of a preferred embodiment of a leadframe 10 illustrating an indentation 34 on the surface 22 of the anchor pad 20 arranged in a substantially circular pattern 24. In other respects, the embodiment shown in FIG. 5 is similar to that shown in, and described with reference to, FIG. 2, including the increase in surface area and edge areas 28.

FIG. 6 is a macro view of a portion of a leadframe 10 according to the invention depicting an anchor pad 20 exhibiting additional alternative embodiments. As shown, cut-outs in the form of circular holes 36 may be used as a conveniently manufacturable enhancement of the anchor pad 20 surface 22. As described elsewhere, indented 38 or embossed 40 patterns 24 may also be used. As can be seen in FIG. 6, a pattern 24 of variously indented, embossed, or cut-out 36 portions of the surface 22 may be used, all having edges 28 to promote bond formation, either in combination or independently (as shown in FIGS. 1-5) within the scope of the invention. Pattern configurations are virtually limitless, and metal of alloy surface plating possibilities are myriad, as long as anchor pad 20 surfaces 22 and materials conducive to superior metallurgical bond formation are used.

The methods and systems of the invention provide one or more advantages including but not limited to improved semiconductor device package strength and durability. The improved anchor pad bond strength and stability gained when using the invention may also result in improvements in metallurgical bonds elsewhere on the leadframe, such as leadfingers and bond pads. Additionally, increased mechanical strength and durability in packages using the invention in some instances may be used to provide increased design flexibility beneficial to other, electrical, connections within the package. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

We claim:

1. A semiconductor device leadframe comprising:
an approximately rectangular sheet metal body, the body having an interior semiconductor device mounting site for receiving a semiconductor device, and also having leadfingers extending from the proximity of the device mounting site to the outer edges of the leadframe; and
an anchor pad situated at each corner of the leadframe body, each anchor pad further comprising a patterned surface.

2. A semiconductor device leadframe according to claim 1 wherein each anchor pad further comprises a substantially rectangular area having a metallic surface punctuated by a plurality of indentations.

3. A semiconductor device leadframe according to claim 1 wherein each anchor pad further comprises a substantially rectangular area having a metallic surface punctuated by a plurality of embossed portions.

4. A semiconductor device leadframe according to claim 1 wherein each anchor pad further comprises a substantially rectangular area having a metallic surface punctuated by a plurality of cut-outs.

5. A semiconductor device leadframe according to claim 1 wherein each anchor pad further comprises a substantially a metallic surface bearing a substantially grid-like pattern.

6. A semiconductor device leadframe according to claim 1 wherein each anchor pad further comprises a substantially rectangular area having a metallic surface bearing a substantially circular pattern.

7. A semiconductor device leadframe according to claim 1 wherein each anchor pad further comprises a metallic surface plated with a low-melting point alloy.

8. A semiconductor device leadframe according to claim 1 wherein each anchor pad further comprises a metallic surface plated with a low-melting point alloy consisting of two or more metals selected from the group: nickel, palladium, gold, silver, copper, tin.

9. A semiconductor device leadframe according to claim 1 wherein each anchor pad further comprises a metallic surface plated with a low-melting point alloy comprising nickel, palladium, and gold.

10. A semiconductor device leadframe according to claim 1 wherein each anchor pad further comprises a metallic surface plated with a low-melting point alloy comprising tin, silver, and copper.

11. A method for making a semiconductor device leadframe comprising the steps of:
providing a substantially rectangular sheet metal body, the body having an interior semiconductor device mounting site for receiving a semiconductor device, and also having leadfingers extending from the proximity of the device mounting site to the outer edges of the leadframe, and an anchor pad situated at each corner of the leadframe body; and
forming a patterned surface on each anchor pad.

12. A method according to claim 11 wherein the step of forming a patterned surface on each anchor pad further comprises forming a pattern of indentations into the surface of each anchor pad.

13. A method according to claim 11 wherein the step of forming a patterned surface on each anchor pad further comprises forming a pattern of cut-outs into the surface of each anchor pad.

14. A method according to claim 11 wherein the step of forming a patterned surface on each anchor pad further comprises the step of stamping each anchor pad.

15. A method according to claim 11 wherein the step of forming a patterned surface on each anchor pad further comprises the step of etching each anchor pad.

16. A method according to claim 11 wherein the step of forming a patterned surface on each anchor pad further comprises the step of drilling each anchor pad.

17. A method according to claim 11 wherein the step of forming a patterned surface on each anchor pad further comprises forming a substantially grid-like patterned surface on each anchor pad.

18. A method according to claim 11 wherein the step of forming a patterned surface on each anchor pad further comprises forming a substantially circular patterned surface on each anchor pad.

19. A method according to claim 11 further comprising the step of plating each patterned anchor pad surface with a low-melting point alloy.

20. A method according to claim 11 further comprising the step of plating each patterned anchor pad surface with a low-melting point alloy consisting of two or more metals selected from the group: nickel, palladium, gold, silver, copper, tin.

21. A semiconductor device package comprising:
a metallic leadframe having an approximately rectangular body, the body having a semiconductor device mounting site for receiving a semiconductor device, and also having leadfingers extending from the proximity of the device mounting site to the outer edges of the leadframe;
a semiconductor device affixed to the device mounting site and operably coupled to the leadfingers;
four tie bars extending from the device mounting site and terminating at anchor pads pad situated at each corner of the leadframe body, each anchor pad further comprising a patterned surface;
a mold compound substantially encapsulating the semiconductor device, and one surface of the leadframe, wherein the patterned surface of each anchor pad remains exposed for receiving a metallic bond.
